(19) United States
(12) Patent Application Publication
(10) Pub. No.: US 2025/0293652 A1
(43) Pub. Date: Sep. 18, 2025

(54) VARIABLE INDUCTANCE SYSTEMS AND METHODS FOR HIGH FREQUENCY GAIN CONTROL

(71) Applicant: MAXIM INTEGRATED PRODUCTS, INC., San Jose, CA (US)

(72) Inventors: Abdelrahman Hesham Elsayed Ahmed, Vancouver (CA); Ariel Leonardo Vera Villarroel, Lake Oswego, OR (US)

(73) Assignee: MAXIM INTEGRATED PRODUCTS, INC., San Jose, CA (US)

(21) Appl. No.: 18/652,671

(22) PCT Filed: Nov. 1, 2022
(86) PCT No.: PCT/US2022/048520

§ 371 Date: May 1, 2024

Related U.S. Application Data
(60) Provisional application No. 63/274,694, filed on Nov. 2, 2021.

(51) Int. Cl. H03G 3/30; H03F 3/45; H04B 10/564

(52) U.S. Cl. CPC H03G 3/3036; H03F 3/45237; H03G 2201/103; H04B 10/564

(57) ABSTRACT

Various embodiments of the invention provide amplifier control systems and methods for adjusting a high frequency gain of an amplifier circuit. In certain embodiments, this is accomplished by varying an effective inductance of an amplifier circuit that comprises a first path, which comprises a first cascoded transistor in series with a first inductor and a second cascoded transistor in parallel with the first cascoded transistor. A second path to carry a second current in parallel with the first path comprises a third cascoded transistor that is coupled in series with a second inductor, wherein adjusting comprises maintaining the sum of the first and second currents to be substantively constant when alternating current between the second and third transistors.

### CROSS REFERENCE TO RELATED PATENT APPLICATIONS

The present application is a 371 National Phase application of, and claims priority to PCT Patent Application Serial No. PCT/US22/48520, filed Nov. 1, 2022 entitled “VARIABLE INDUCTANCE SYSTEMS AND METHODS FOR HIGH FREQUENCY GAIN CONTROL”, and listing as inventors Abdelrahman Hesham Elsayed Ahmed and Ariel Leonardo Vera Villarroel, which claims priority benefit, under 35 U.S.C. §119(e), to co-pending and commonly-assigned U.S. Provisional Patent Application No. 63/274,694, filed on Nov. 2, 2021, entitled “VARIABLE INDUCTANCE SYSTEMS AND METHODS FOR HIGH FREQUENCY GAIN CONTROL”, and listing as inventors Abdelrahman Hesham Elsayed Ahmed and Ariel Leonardo Vera Villarroel. Each reference mentioned in this patent document is incorporated by reference herein in its entirety.

### BACKGROUND

### A. Technical Field

The present disclosure relates generally to amplifier circuits. More particularly, the present disclosure relates to systems and methods for controlling amplifier gain, especially, for high-frequency applications such as optical communication systems.

### B. Background

In optical communication systems, information travels in the form of light, yet interactions between components in a communication link occur in the electrical domain. Transducers convert communications signals from the electrical to the optical domain and vice versa.

In the electrical domain, components of a communications link are typically designed to maximize the amount of information that can be transmitted, for example, by optimizing the frequency response of one or more circuit components, or by implementing functionality that allows for more sophisticated modulation schemes. Controlling gain at high frequencies is oftentimes used to compensate for losses that originate within the link at such frequencies. Various existing approaches attempt to improve frequency response and, thus, bandwidth to achieve higher throughput. In practice, each of these approaches has a different trade-off in overall link performance, e.g., power consumption, area requirements, and the like. In addition, in practice, process, voltage, and temperature variations negatively impact a link's component performance, further reducing system performance.

Accordingly, it is highly desirable to have new and improved systems and methods that allow gain control at high-frequency operation, without negatively impacting the low-frequency operation of a circuit.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not to scale.

FIG. 1 depicts a simplified block diagram of a section of a high-frequency communications link, according to various embodiments of the present disclosure.

FIG. 2 shows a common cascoded differential amplifier topology.

FIG. 3 shows a cascoded differential amplifier topology used for its high gain at high frequencies.

FIG. 4 is a simplified diagram depicting a variable inductance approach for controlling amplifier gain at high frequencies in a communication link, such as that in FIG. 1.

FIG. 5 illustrates an exemplary implementation of an amplifier utilizing a variable inductance to control amplifier gain at high frequencies according to various embodiments of the present disclosure.

FIG. 6 and FIG. 7 illustrate example implementations for maintaining optimum transistors current density in an amplifier circuit according to various embodiments of the present disclosure.

FIG. 8 is a graph that shows plots of normalized frequency responses of an amplifier utilizing a variable inductance for high frequency gain control according to various embodiments of the present disclosure.

FIG. 9 is a flowchart of an illustrative process for adjusting a high frequency gain of an amplifier circuit, according to various embodiments of the present disclosure.

### DETAILED DESCRIPTION OF EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be implemented in a variety of ways, such as a process, an apparatus, a system, a device, or a method on a tangible computer-readable medium.

Components, or modules, shown in diagrams are illustrative of exemplary embodiments of the invention and are meant to avoid obscuring the invention. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” or “communicatively coupled” shall be understood to include direct connections, indirect connections through one or more intermediary devices, and wireless connections.

Reference in the specification to “one embodiment,” “preferred embodiment,” “an embodiment,” or “embodiments” means that a particular feature, structure, characteristic, or function described in connection with the embodiment is included in at least one embodiment of the invention and may be in more than one embodiment. Also, the appearances of the above-noted phrases in various places in the specification are not necessarily all referring to the same embodiment or embodiments.

The use of certain terms in various places in the specification is for illustration and should not be construed as limiting. A service, function, or resource is not limited to a single service, function, or resource; usage of these terms may refer to a grouping of related services, functions, or resources, which may be distributed or aggregated.

The terms “include,” “including,” “comprise,” and “comprising” shall be understood to be open terms and any lists the follow are examples and not meant to be limited to the listed items. Any headings used herein are for organizational purposes only and shall not be used to limit the scope of the description or the claims. Each reference mentioned in this patent document is incorporate by reference herein in its entirety.

It is noted that embodiments described herein are given in the context of differential broadband high-frequency amplifiers, but one skilled in the art will recognize that the teachings of the present disclosure are not limited to the applications and may equally be used in other contexts.

There exist a considerable number of approaches for increasing the gain of a link component at high frequencies. One approach involves optimizing the DC operating conditions for common active devices, e.g., a bipolar junction transistor (BJT) or a metal oxide semiconductor field-effect transistor (MOSFET) in the circuit that implements the link component, such as an amplifier. However, this optimization is limited by the process technology and the engineered active devices within such technology. Another approach involves using a technology that focuses on improving frequency response, which drives the creation of new technologies for circuit design, along with reduced power consumption and area, e.g., for higher integration. Active devices circuit topologies maximize the gain at high frequencies. One of the most widespread techniques is the use of cascode devices, where a first transistor is cascoded by a second transistor, thereby, increasing circuit output impedance and reducing its input capacitive loading, consequently, high-frequency gain. Although inductors, routinely integrated on-chip, have become essential in increasing gain at high frequencies, due to the nature of their implementation (i.e., the inductor being constructed using metal layers that are available based on the technology that is used to fabricate the chip), their inductance is limited to a fixed value that cannot be changed post-fabrication, thus, making their performance improvement-sensitive to process, temperature, and voltage variations.

Accordingly, it is highly desirable to have technology-independent solutions that allow post-fabrication gain control at high frequencies by controlling the effective inductance during circuit operation, e.g., to compensate for process, voltage, and temperature variations.

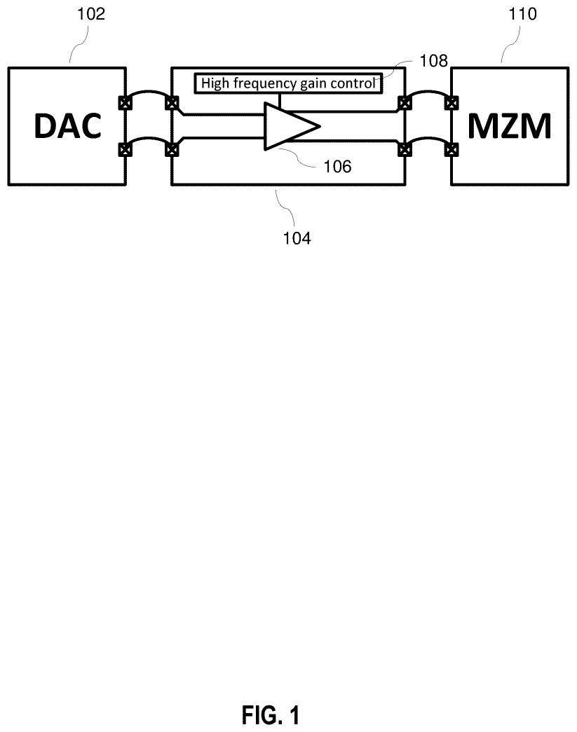

FIG. 1 depicts a simplified block diagram of an exemplary section of a high-frequency communications link, according to various embodiments of the present disclosure. Communications link 100, which may be implemented, e.g., in an optical link driver, comprises digital-to-analog converter (DAC) 102 coupled to high-frequency circuit 104, which may be implemented on a chip. High-frequency circuit 104, is coupled to Mach-Zehnder modulator 110 and comprises both amplifier 106 and high-frequency control 108 that also may be integrated on-chip.

As shown, in FIG. 1, the output of amplifier 106, which may be characterized by the amount of gain for a given frequency range, drives Mach-Zehnder modulator 110. In certain applications, it is desirable to be able to adjust the gain at high frequencies, ideally, without sacrificing gain at lower frequencies, or any other desirable properties.

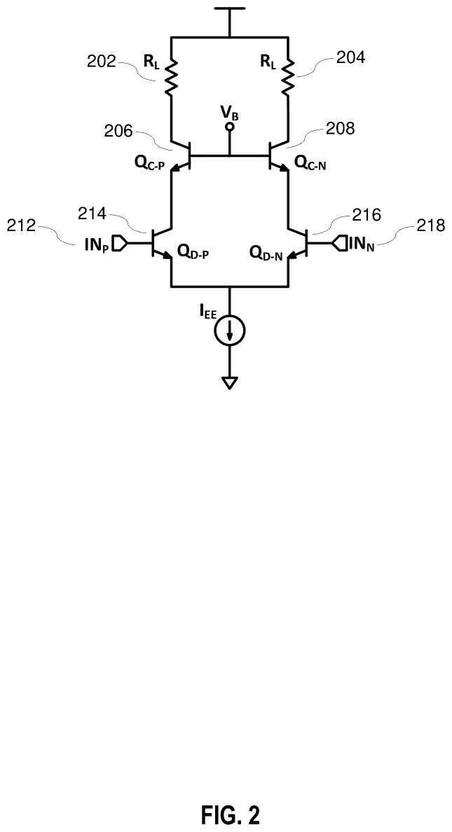

FIG. 2 shows a common cascoded differential amplifier topology. Circuit 200 comprises resistors 202-204, current source 220, and transistors 214-216, which provide gain and are cascoded by transistors 206-208, whose base terminals are biased by a common voltage 210. As depicted, the base terminals of transistors 214-216 serve as circuit inputs 212 and 218, respectively; and the emitters of transistors 214-216 are coupled to current source 220, such that their combined emitter currents equal I_{EE}.

Cascoded differential amplifier architecture 200 is typically used for its high bandwidth, high gain, and high output impedance. As a person of skill in the art will understand, circuit 200 need not necessarily be implemented with bipolar transistors any type of transistor design may be used, including, e.g., Metal-Oxide-Semiconductor Field-Effect Transistors (MOSFETs), or a combination different transistor types, such as a combination of a MOSFET transistor and a BJT.

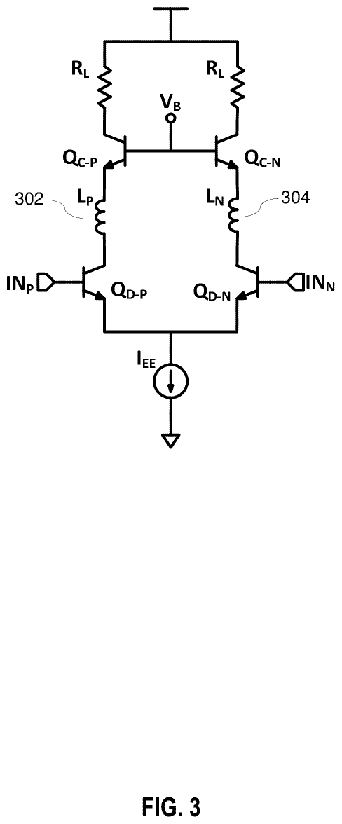

FIG. 3 shows a cascoded differential amplifier topology commonly used for its high gain at high frequencies. Same numerals as in FIG. 2 denote similar elements. As depicted, circuit 300 utilizes inductors 302 and 304 (denoted as respective inductors L_{P} and L_{N}) that are coupled between the emitters of transistors 206-208 of the cascoded BJT pair and the collectors of transistors 214-216. This technique allows to increase the gain at high frequencies without affecting the gain at low frequencies. However, due to the inductances of inductors 302 and 304 being fixed by their geometry, the high frequency gain they enable is not variable. In other words, the gain of amplifier 300 cannot be adjusted by varying inductance. Therefore, it would be desirable to have flexible systems and methods that allow for the implementation of adjustable inductances that facilitate gain control in broad-band applications.

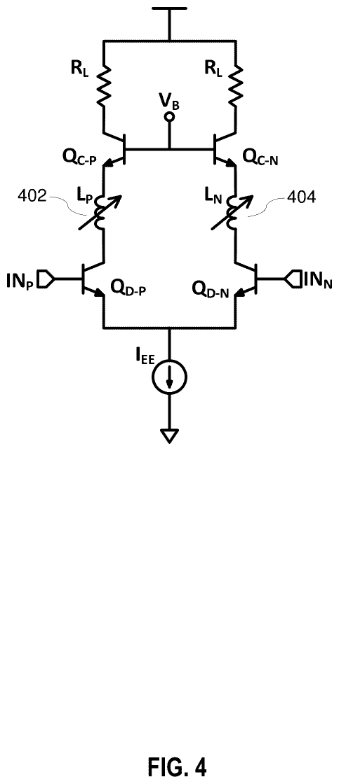

FIG. 4 is a simplified diagram depicting a variable inductance approach for controlling amplifier gain in a communication link, e.g., that in FIG. 1. For clarity, same numerals as in FIG. 2 denote similar elements. Unlike the fixed inductance values of the inductors shown in FIG. 3, circuit 400 in FIG. 4 comprises a cascode pair with inductors 402-404 having variable inductance that are connected to the differential pair 414-416. The variable inductors 402 and 404 are denoted as L_{P} and L_{N}. In embodiments, variable inductors 402-404 may, depending on application and frequency range, be implemented as discrete or distributed components. For example, in embodiments, at the low GHz frequency range, any number of inductors may be disposed in close physical proximity to each other on upper metal layers of a PCB, e.g., to reduce stray capacitance and maintain high performance.

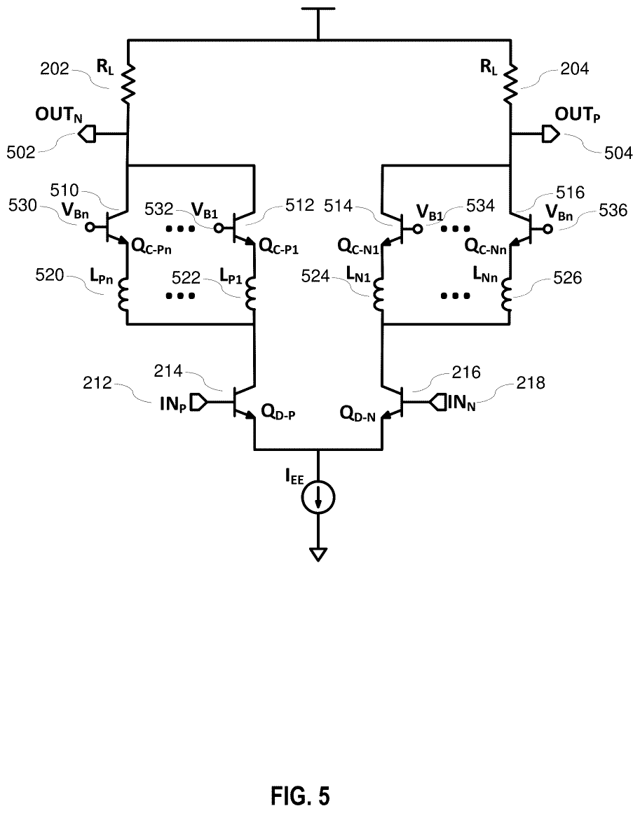

FIG. 5 illustrates an exemplary implementation of an amplifier utilizing a variable inductance to control amplifier gain according to various embodiments of the present disclosure. Again, components similar to those shown in FIG. 2 are labeled in the same manner. As with FIG. 2, circuit 500 may comprise additional elements, such as coupling capacitors, voltage supplies, impedance matching circuitry, and so on, which may be arranged depending on the objectives of a particular application.

In operation, by switching between paths that comprise different transistors, each associated with a different inductor, the effective inductance of circuit 500 may be varied depending on which transistor pair is active at any moment in time. As a result, in embodiments, variable inductances may be utilized to realize and control different amplifier gain values at the high frequency range. Advantageously, various embodiments herein allow performing gain control post-fabrication.

As shown, the differential pair structure of FIG. 4 is maintained in circuit 500 in FIG. 5, with a major difference that the cascode pair of inductors in FIG. 4 is replaced by a set of n transistors 510-516 that are connected in a parallel circuit configuration. In embodiments, each of transistors 510-516 is coupled in a series configuration with a respective inductor 520-526. The ON/OFF control of transistors 510-516 may be facilitated by a controller (not shown) that independently controls the bias voltages of transistors 510-516. Outputs 502, 504 are coupled to collectors of transistors 510-516.

In operation, although any number n of transistors may be connected in parallel, in embodiments, two transistors are active (i.e., turned ON) to form an active transistor pair, while the remaining transistors are inactive (i.e., turned OFF). In such implementations, the effective inductance of circuit 500 is defined mainly by the inductances of those inductor pairs that correspond to the transistor pairs that are turned ON. Therefore, in embodiments, having inductors 520-526 with varying values, e.g., in the tens to hundreds of pH range, allows designers to select and adjust the effective inductance of signal paths post-fabrication. In embodiments, by switching between configurations of transistors associated with different inductance values, the high-frequency gain of amplifier 500 may thus be varied, e.g., in number of discrete steps.

Furthermore, the ability to turn ON two or more transistors at the same time enables designers to adjust the effective inductance, e.g., by selecting a suitable parallel combination of any number of inductors whose transistors may be turned ON. However, since the available tail current, I_{EE}, 220, which together with resistor 202 defines the gain at low frequencies, is distributed among all transistor that are turned ON, and which define the gain at high frequencies, optimum current density biasing of each transistor that, ideally, is sized for a certain current density to achieve optimum performance at a certain operating point, can generally not be achieved.

For example, turning on transistors 510 and 512 at the same time would cause the current density at each of respective transistor 510, 512 to be split (e.g., in half) due to their parallel combination. Therefore, it would be desirable to have elegant systems and methods that, in instances when four (or more) transistors are turned ON at the same time in circuit 500, allow all transistors to continue to operate at their optimum current density to achieve the highest bandwidth at the fasted possible speed.

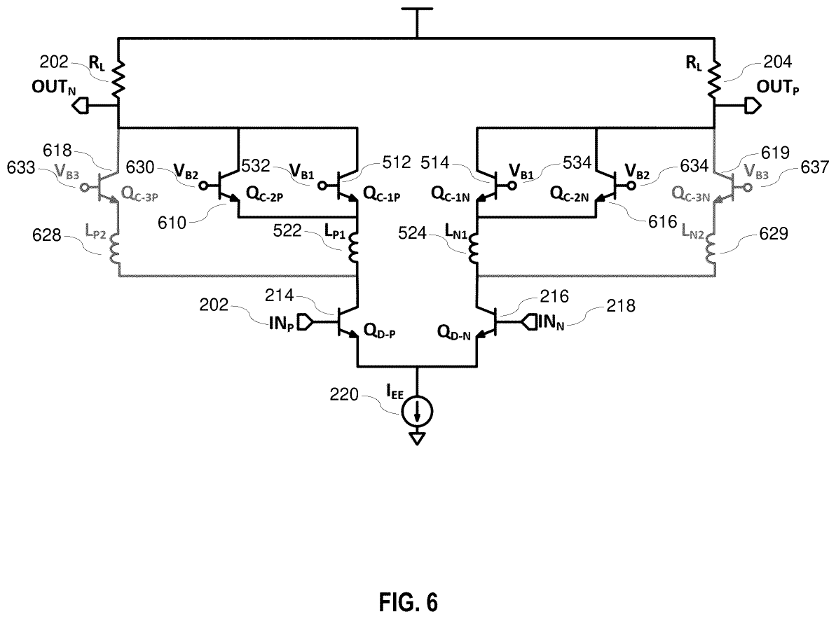

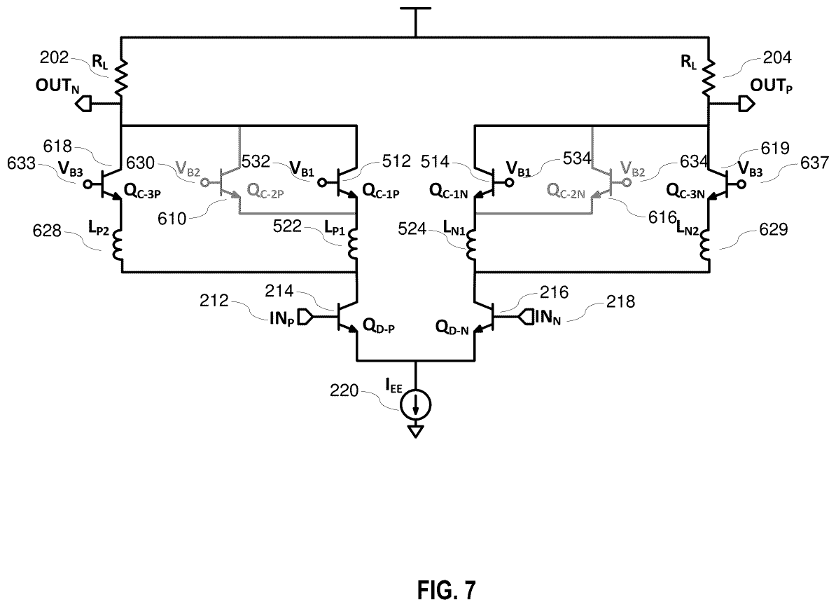

Example implementations for improving current density biasing for two active transistors in each branch of a differential cascode are illustrated in FIG. 6 and FIG. 7. Circuits 600 and 700 in respective FIG. 6 and FIG. 7 comprise input transistors 214, 216 and cascode transistors 512, 514, 610, 616, 618, and 619; current source 220; and resistors 202, 204. It is noted that the implementations illustrated in FIG. 6 and FIG. 7 are not limited to the constructional detail shown therein or described in the accompanying text. As those skilled in the art will appreciate, different and/or additional components may be used, e.g., a control circuit that may comprise microcontrollers, logic elements, and any other control elements recognized by one of skilled in the art. Other components may comprise coupling capacitors, voltage supplies, impedance matching circuitry, and the like, that may be arranged depending on application.

For example, although three paths in each branch of the differential cascode are shown, this is not intended as a limitation on the scope of the present disclosure as any arbitrary number of paths may be used to accomplish the objectives herein. Similarly, it is understood that although bipolar transistors are depicted in FIG. 6 and FIG. 7, CMOS or other technologies may equally be implemented with the scope of the present disclosure.

In embodiments, transistors 618-619 are turned OFF, as indicated by the greyed out path in FIG. 6; and transistors 512, 514, 610, 616 are turned ON, such that the effective inductance of amplifier circuit 600 is substantially defined by the inductance values of inductors 522-524. Assuming that amplifier 600 has a total current of 20 mA, for transistors 512, 514, 610, and 616 to operate at or near their optimum operating point, which as a person of skill in the art will appreciate is technology dependent, a current density is 1.25 mA/um² is assumed.

For comparison, returning to the design shown in FIG. 5, where each of transistors 214 and 512 (denoted as Q_{D-P} and Q_{C-P1}) in the left branch conducts a current of 10 mA and transistor 510 is turned OFF, assuming that each transistor is sized to have an area of 8 μm², once transistors 214 and 512 operate at their optimum point, the current density at each transistor 214 and 512 will be 1.25 mA/μm², and the effective inductance of the left branch circuit 500 in FIG. 5 will be that of inductor L_{P1} 522.

Further, once transistor Q_{C-Pn} 510 is also enabled, assuming that inductor 520 has the same inductance L_{Pn} as inductor 522, i.e., L_{P1}, since both inductors 520 and 522 are now coupled in parallel, the effective inductance of the left branch will assume a value of L_{P1}/2 (assuming L_{P1}=L_{P2}). Further, both transistors 510 and 512 will each conduct a current of 5 mA. Given the transistor size of 8 μm², the current density at each transistor will thus be 0.625 mA/μm², which is far from the optimum operation point of the transistors.

In contrast, for circuit 600 shown in FIG. 6, assuming that transistors 512, 514, 610, 616, 618, and 619 have a nominal area of 4 μm² and conduct 5 mA each when turned ON to operate at their optimum point, and further assuming that transistor 512 remains turned ON and transistors 610 and 618 alternately turn ON and OFF according to the goals of the present disclosure, e.g., transistor 610 Q_{C-2P} is turned ON in FIG. 6, and transistor 618 is turned OFF, only one inductor, inductor 522, carries a current in the left branch, and active transistors 512, 610, and 214 operate at current a density of 1.25 mA/μm².

As shown in FIG. 7, once transistor 610 is turned OFF and transistor 618 is turned ON, the current flows through both inductors 522 and 628. Assuming L_{P1} and L_{P2} have equal inductance values of 50 pH, their effective inductance becomes 25 pH due to their parallel circuit combination. As in FIG. 5, switching between transistor configuration settings that have different inductance values, in embodiments, circuit 700 may vary amplifier gain at high-frequencies in a number of discrete steps; however, each of the four transistors 512-514, 618, and 619 in FIG. 7 that is turned ON is still biased at its optimum current density, as one quarter (e.g., 5 mA) of the tail current I_{EE} (e.g., 20 mA) flows through each transistor. As a result, advantageously, all transistors may continue to operate at their optimum current density, here, 1.25 mA/μm².

Further, it is noted that in the implementations illustrated in FIG. 6 and FIG. 7, the capacitive load at the output is lower than in that in the implementation in FIG. 4 due to the fact that in circuits 600 and 700, when two transistors are turned ON in each branch of the differential amplifier, each transistor, 512, 610 and 514, 616 in circuit 600, and 512, 618 and 514, 619 in circuit 700, carries one quarter of the tail current I_{EE}. As a result, the area of each transistor in FIG. 6 and FIG. 7 may be sized half of the transistors shown in FIG. 5, where a single transistor carries half of the entire tail current. Furthermore, since transistor area is approximately proportional to parasitic capacitance, each inactive transistor in FIG. 6 and FIG. 7 contributes only half the parasitic capacitance of those in FIG. 5.

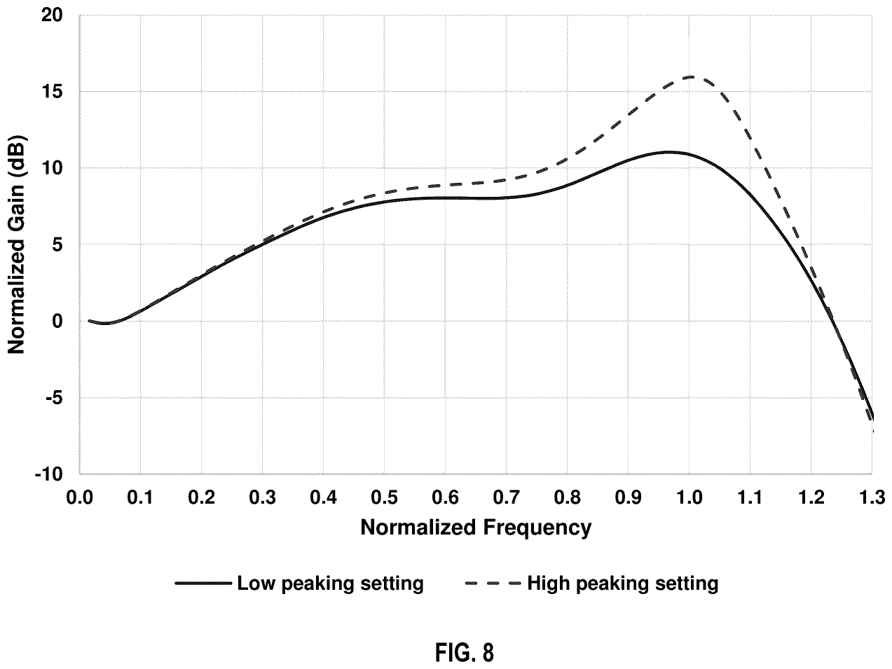

FIG. 8 is a graph that shows plots of normalized frequency responses of an amplifier utilizing a variable inductance for high frequency gain control according to various embodiments of the present disclosure. The dashed line corresponds to the implementation in FIG. 6 with inductor L_{P1} having in inductance value of 50 pH; and the solid line corresponds to the implementation in FIG. 7 with inductors L_{P1} and L_{P2} in parallel having a combined inductance value of 25 pH.

It is noted that experimental data and results herein are provided by way of illustration and were performed under specific conditions using a specific embodiment or embodiments; accordingly, neither these experiments nor their results shall be used to limit the scope of the disclosure of the current patent document.

As shown in FIG. 8, the gain control mechanism allows to change the gain (denoted in dB) around the frequency of interest, e.g., 60 GHz, normalized to 1 on the x-axis. The overall gain control range in this implementation is about 6 dB. As depicted in FIG. 8, peaking in the transfer function is more pronounced at the high-frequency end of the response and has relatively little effect at the low and mid-range frequencies, indicating that varying the inductance affects the relationship of output voltage relative to the input voltage.

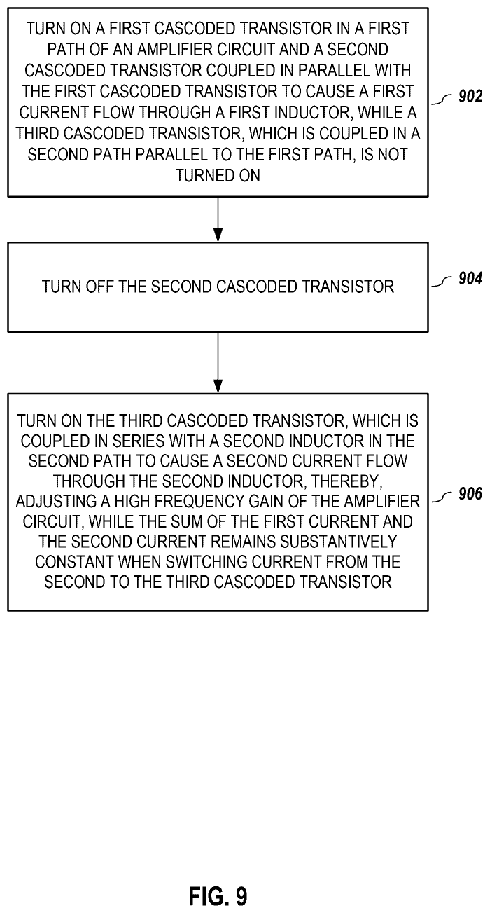

FIG. 9 is a flowchart of an illustrative process for adjusting a high frequency gain of an amplifier circuit, according to various embodiments of the present disclosure. In embodiments, process 900 may begin, at step 902, when a first cascoded transistor in a first path of the amplifier circuit and a second cascoded transistor that is coupled in parallel with the first cascoded transistor are turned ON to cause a first current flow through a first inductor. At step 902, a third cascoded transistor, which is coupled in a second path parallel to the first path, is not turned on.

At step 904, the second cascoded transistor is turned off.

At step 906, the third cascoded transistor, which is coupled in series with a second inductor in the second path, is turned on to cause a second current flow through the second inductor to adjust an effective inductance in the amplifier circuit, thereby, adjusting a high frequency gain of the amplifier circuit. In embodiments, the sum of the first current and the second current remains substantively constant when alternating current flow between the second and third cascoded transistors.

One skilled in the art shall recognize that: (1) certain steps may optionally be performed; (2) steps may not be limited to the specific order set forth herein; (3) certain steps may be performed in different orders; and (4) certain steps may be done concurrently.

Aspects of the present invention may be encoded upon one or more non-transitory computer-readable media with instructions for one or more processors or processing units to cause steps to be performed. It shall be noted that the one or more non-transitory computer-readable media shall include volatile and non-volatile memory. It shall be noted that alternative implementations are possible, including a hardware implementation or a software/hardware implementation. Hardware-implemented functions may be realized using application specific integrated circuits (ASICs), programmable arrays, digital signal processing circuitry, or the like. Accordingly, the terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that embodiments of the present invention may further relate to computer products with a non-transitory, tangible computer-readable medium that have computer code thereon for performing various computer-implemented operations. The media and computer code may be those specially designed and constructed for the purposes of the present invention, or they may be of the kind known or available to those having skill in the relevant arts. Examples of tangible computer-readable media include, but are not limited to: magnetic media such as hard disks; optical media such as CD-ROMs and holographic devices; magneto-optical media; and hardware devices that are specially configured to store or to store and execute program code, such as ASICs, programmable logic devices (PLDs), flash memory devices, and ROM and RAM devices. Examples of computer code include machine code, such as produced by a compiler, and files containing higher level code that are executed by a computer using an interpreter. Embodiments of the present invention may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the present invention. One skilled in the art will also recognize that a number of the elements described above may be physically and/or functionally separated into sub-modules or combined together.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies. configurations, and combinations.

1. An amplifier circuit comprising:
a first path within the amplifier circuit to carry a first current, the first path comprising:
a first cascoded transistor;
a first inductor coupled in series with the first cascoded transistor; and
a second cascoded transistor coupled in parallel with the first cascoded transistor; and
a second path to carry a second current, the second path being coupled in parallel with the first path and comprising:
a third cascoded transistor; and
a second inductor coupled in series with the third cascoded transistor, at least two of the first, second, or third cascoded transistors being activated to adjust a high frequency gain of the amplifier circuit by varying an effective inductance of the amplifier circuit, while maintaining a sum of the first current and the second current to be constant.

2. The amplifier circuit of claim 1, wherein the first current and the second current are the same.

3. The amplifier circuit of claim 1, further comprising a fourth transistor coupled in series with the first inductor, the fourth transistor serving as an input to the amplifier circuit.

4. The amplifier circuit of claim 3, further comprising a current source coupled in series with the fourth transistor first inductor, the current source carrying a tail current that remains the same during operation of the amplifier circuit.

5. The amplifier circuit of claim 1, further comprising an output that is coupled to a collector of the third cascoded transistor.

6. The amplifier circuit of claim 1, wherein the amplifier circuit is implemented as a differential amplifier circuit.

7. The amplifier circuit of claim 6, wherein the differential amplifier circuit receives a common voltage.

8. An amplifier control method comprising:
adjusting a high frequency gain of an amplifier circuit by varying an effective inductance of the amplifier circuit, which comprises:
a first path comprising a first cascoded transistor in series with a first inductor and a second cascoded transistor coupled in parallel with the first cascoded transistor; and
a second path to carry a second current, the second path being coupled in parallel with the first path and comprising:
a third cascoded transistor; and
a second inductor coupled in series with the third cascoded transistor, wherein adjusting comprises maintaining a sum of the first current and the second current to be constant when alternating current flow between the second and third cascaded transistors.

9. The amplifier control method of claim 8, wherein the first current and the second current are the same.

10. The amplifier control method of claim 8, further comprising using a fourth transistor, which is coupled in series with the first inductor, an input to the amplifier circuit.

11. The amplifier control method of claim 10, further comprising using a current source, which is coupled in series with the fourth transistor first inductor, to carry a tail current that remains the same during operation of the amplifier circuit.

12. The amplifier control method claim 8, wherein the amplifier circuit is implemented in as a differential amplifier circuit.

13. The amplifier control method claim 8, wherein varying an effective inductance of the amplifier circuit comprises turning on the first cascoded transistor to cause a first current flow through the first inductor, turning off the second cascoded transistor, and turning on the third cascoded transistor to cause the second current to flow through the second inductor.

14. A high-frequency communications link using an amplifier circuit, the communications link comprising:
a digital-to-analog converter (DAC);
an amplifier circuit coupled to the DAC, the amplifier circuit comprising:
a first path within the amplifier circuit to carry a first current, the first path comprising:
a first cascoded transistor;
a first inductor coupled in series with the first cascoded transistor; and
a second cascoded transistor coupled in parallel with the first cascoded transistor; and
a second path to carry a second current, the second path being coupled in parallel with the first path and comprising:
a third cascoded transistor; and
a second inductor coupled in series with the third cascoded transistor; and
a high-frequency gain controller coupled to the amplifier circuit, the high-frequency gain controller causes at least two of the first, second, or third cascoded transistors to be activated to adjust a high frequency gain of the amplifier circuit by varying an effective inductance of the amplifier circuit, while maintaining a sum of the first current and the second current to be constant; and
a Mach-Zehnder modulator coupled to the amplifier circuit, the Mach-Zehnder modulator being driven by the amplifier circuit

15. The communications link of claim 14, wherein the first current and the second current are the same.

16. The communications link of claim 14, further comprising a fourth transistor coupled in series with the first inductor, the fourth transistor serving as an input to the amplifier circuit.

17. The communications link of claim 16, further comprising a current source coupled in series with the fourth transistor first inductor, the current source carrying a tail current that remains the same during operation of the amplifier circuit.

18. The communications link of claim 14, further comprising an output that is coupled to a collector of the third cascoded transistor.

19. The communications link of claim 18, wherein the amplifier circuit is implemented as a differential amplifier circuit.

20. The communications link of claim 14, wherein the amplifier circuit is implemented in as a differential amplifier circuit.
